(19) United States
(12) Patent Application Publication
(10) Pub. No.: US 2025/0006624 A1
(43) Pub. Date: Jan. 2, 2025

(54) SEMICONDUCTOR DEVICE

(71) Applicant: Sumitomo Electric Device Innovations, Inc., Yokohama-shi (JP)

(72) Inventor: Hiroaki MARUYAMA, Yokohama-shi (JP)

(73) Assignee: Sumitomo Electric Device Innovations, Inc., Yokohama-shi (JP)

(21) Appl. No.: 18/739,637

(22) Filed: Jun. 11, 2024

(30) Foreign Application Priority Data
Jun. 30, 2023 (JP) 2023-108429

(51) Int. Cl. H01L 23/522; H01L 21/8252; H01L 23/48; H01L 27/095; H01L 29/20; H01L 29/66; H01L 29/778

(52) U.S. Cl. CPC H01L 23/5221; H01L 21/8252; H01L 23/481; H01L 27/095; H01L 29/2003; H01L 29/66462; H01L 29/7786

(57) ABSTRACT

A semiconductor device includes a substrate, a first transistor unit having a first drain electrode, a first gate electrode, and a first source electrode, a second transistor unit having a second source electrode, a second gate electrode, and a second drain electrode, a gate wiring provided between the first source electrode and the second source electrode and electrically connected to the first gate electrode and the second gate electrode, a first cover metal layer electrically connected to the first source electrode, at least an upper portion of the first cover metal layer projecting toward the gate wiring more than the first source electrode, and a second cover metal layer electrically connected to the second source electrode, at least an upper portion of the second cover metal layer projecting toward the gate wiring more than the second source electrode.

### CROSS REFERENCE TO RELATED APPLICATIONS

This application claims priority based on Japanese Patent Application No. 2023-108429 filed on Jun. 30, 2023, and the entire contents of the Japanese patent applications are incorporated herein by reference.

### FIELD

A certain aspect of the embodiments is related to a semiconductor device.

### BACKGROUND

In a field effect transistor (FET) having a finger-shaped source electrode, a finger-shaped gate electrode, and a finger-shaped drain electrode, it is known that a plurality of unit FETs each having the source electrode, the gate electrode, and the drain electrode are arranged in an extending direction of the electrodes (for example, Patent Document 1: Japanese Laid-Open Patent Application No. 2002-299351).

### SUMMARY

A semiconductor device according to the present disclosure includes: a substrate; a first transistor unit having a first drain electrode, a first gate electrode, and a first source electrode which are provided in order on the substrate; a second transistor unit having a second source electrode arranged along the first source electrode and electrically connected to the first source electrode, a second gate electrode electrically connected to the first gate electrode, and a second drain electrode electrically connected to the first drain electrode, the second source electrode, the second gate electrode and the second drain electrode being provided in order on the substrate, the second transistor unit being located in a direction where the first drain electrode, the first gate electrode, and the first source electrode are arranged with respect to the first transistor unit; a gate wiring provided on the substrate between the first source electrode and the second source electrode and adjacent to the first source electrode and the second source electrode, and electrically connected to the first gate electrode and the second gate electrode; a first cover metal layer provided on and electrically connected to the first source electrode, at least an upper portion of the first cover metal layer projecting toward the gate wiring more than the first source electrode; and a second cover metal layer provided on and electrically connected to the second source electrode, at least an upper portion of the second cover metal layer projecting toward the gate wiring more than the second source electrode.

A semiconductor device according to the present disclosure includes: a substrate; a first transistor unit having a first drain electrode, a first gate electrode, and a first source electrode which are provided in order on the substrate; a second transistor unit having a second source electrode arranged along the first source electrode and electrically connected to the first source electrode, a second gate electrode electrically connected to the first gate electrode, and a second drain electrode electrically connected to the first drain electrode, the second source electrode, the second gate electrode and the second drain electrode being provided in order on the substrate, the second transistor unit being located in a direction where the first drain electrode, the first gate electrode, and the first source electrode are arranged with respect to the first transistor unit; a gate wiring provided on the substrate between the first source electrode and the second source electrode and adjacent to the first source electrode and the second source electrode, and electrically connected to the first gate electrode and the second gate electrode; a first source wiring provided on the first source electrode in electrical contact with the first source electrode; a second source wiring provided on the second source electrode in electrical contact with the second source electrode; a first drain wiring provided on the first drain electrode in electrical contact with the first drain electrode, a height of an upper surface of the first drain wiring from the substrate being smaller than a height of an upper surface of the first source wiring from the substrate; and a second drain wiring provided on the second drain electrode in electrical contact with the second drain electrode, and a height of an upper surface of the second drain wiring from the substrate being smaller than a height of an upper surface of the second source wiring from the substrate.

### BRIEF DESCRIPTION OF DRAWINGS

FIG. 1 is a plan view of a semiconductor device according to a first embodiment.

FIG. 2 is an enlarged view of a range D of FIG. 1.

FIG. 3 is a cross-sectional view taken along a line A-A of FIGS. 1 and 2.

FIG. 4 is a cross-sectional view taken along a line B-B of FIGS. 1 and 2.

FIG. 5 is a cross-sectional view taken along a line C-C of FIG. 1.

FIG. 6 is a cross-sectional view illustrating a method for manufacturing the semiconductor device according to the first embodiment.

FIG. 7 is a cross-sectional view illustrating the method for manufacturing the semiconductor device according to the first embodiment.

FIG. 8 is a cross-sectional view illustrating the method for manufacturing the semiconductor device according to the first embodiment.

FIG. 9 is a cross-sectional view illustrating the method for manufacturing the semiconductor device according to the first embodiment.

FIG. 10A is a cross-sectional view illustrating the method for manufacturing the semiconductor device according to the first embodiment.

FIG. 10B is a cross-sectional view illustrating the method for manufacturing the semiconductor device according to the first embodiment.

FIG. 10C is a cross-sectional view illustrating the method for manufacturing the semiconductor device according to the first embodiment.

FIG. 11A is a cross-sectional view illustrating the method for manufacturing the semiconductor device according to the first embodiment.

FIG. 11B is a cross-sectional view illustrating the method for manufacturing the semiconductor device according to the first embodiment.

FIG. 11C is a cross-sectional view illustrating the method for manufacturing the semiconductor device according to the first embodiment.

FIG. 12 is a cross-sectional view illustrating the method for manufacturing the semiconductor device according to a first comparative example.

FIG. 13 is an enlarged plan view of a semiconductor device according to a first modification of the first embodiment.

FIG. 14 is a cross-sectional view taken along a line A-A of FIG. 13.

FIG. 15 is a cross-sectional view taken along a line B-B of FIG. 13.

FIG. 16 is an enlarged plan view of a semiconductor device according to a second modification of the first embodiment.

FIG. 17 is a cross-sectional view taken along a line A-A of FIG. 16.

FIG. 18 is an enlarged plan view of a semiconductor device according to a third modification of the first embodiment.

FIG. 19 is a cross-sectional view taken along a line A-A of FIG. 18.

FIG. 20 is a plan view of a semiconductor device according to a second embodiment.

FIG. 21 is a diagram illustrating K-factor with respect to a frequency in semiconductor devices A and B.

FIG. 22 is a diagram illustrating |S12| with respect to a frequency in the semiconductor devices A and B.

### DETAILED DESCRIPTION OF EMBODIMENTS

In Patent Document 1, the width of the gate electrode of the unit FET can be shortened by arranging the plurality of the unit FETs in the extending direction of the electrodes. Therefore, a gate resistance can be suppressed. However, a parasitic capacitance between a drain electrode and a gate wiring electrically connecting a gate pad and a gate electrode away from the gate pad increases, and the characteristics deteriorate.

The present disclosure has been made in view of the above problems, and an object thereof is to suppress deterioration of characteristics.

### Details of Embodiments of the Present Disclosure

First, the contents of the embodiments of this disclosure are listed and explained.

(1) A semiconductor device according to the present disclosure includes: a substrate; a first transistor unit having a first drain electrode, a first gate electrode, and a first source electrode which are provided in order on the substrate; a second transistor unit having a second source electrode arranged along the first source electrode and electrically connected to the first source electrode, a second gate electrode electrically connected to the first gate electrode, and a second drain electrode electrically connected to the first drain electrode, the second source electrode, the second gate electrode and the second drain electrode being provided in order on the substrate, the second transistor unit being located in a direction where the first drain electrode, the first gate electrode, and the first source electrode are arranged with respect to the first transistor unit; a gate wiring provided on the substrate between the first source electrode and the second source electrode and adjacent to the first source electrode and the second source electrode, and electrically connected to the first gate electrode and the second gate electrode; a first cover metal layer provided on and electrically connected to the first source electrode, at least an upper portion of the first cover metal layer projecting toward the gate wiring more than the first source electrode; and a second cover metal layer provided on and electrically connected to the second source electrode, at least an upper portion of the second cover metal layer projecting toward the gate wiring more than the second source electrode. This makes it possible to suppress a gate-drain parasitic capacitance and to suppress the deterioration of characteristics.

(2) In the above (1), at least a part of the first cover metal layer and at least a part of the second cover metal layer may overlap with the gate wiring in a non-contact manner in plan view. This makes it possible to further suppress the gate-drain parasitic capacitance and to further suppress the deterioration of the characteristics.

(3) In the above (1) or (2), the first cover metal layer and the second cover metal layer may be in contact with each other above the gate wiring. This makes it possible to further suppress the gate-drain parasitic capacitance and to further suppress the deterioration of the characteristics.

(4) In the above (3), a plurality of first portions where the first cover metal layer and the second cover metal layer are in contact with each other above the gate wiring and a plurality of second portions where the first cover metal layer and the second cover metal layer are not provided above the gate wiring may be alternately provided along the gate wiring. This makes it possible to set the gate-drain parasitic capacitance and a gate-source parasitic capacitance to desired values, and to further suppress deterioration of the characteristics.

(5) In the above (1) or (2), the first cover metal layer and the second cover metal layer may not be in contact with each other above the gate wiring. This makes it possible to suppress the gate-source parasitic capacitance and further suppress the deterioration of the characteristics.

(6) In the above (5), an end of the first cover metal layer may overlap with the gate wiring in plan view, and an end of the second cover metal layer may overlap with the gate wiring in the plan view. This makes it possible to suppress the gate-drain parasitic capacitance and the gate-source parasitic capacitance, and to further suppress the deterioration of the characteristics.

(7) In any one of the above (1) to (6), the semiconductor device further may include a third transistor unit having a third drain electrode electrically connected to the first drain electrode, a third gate electrode electrically connected to the gate wiring, and a third source electrode electrically connected to the first source electrode. The third drain electrode, the third gate electrode and the third source electrode may be provided in order on the substrate. The third transistor unit may be located in a direction where the first gate electrode extends with respect to the first transistor unit. This makes it possible to further suppress the gate-drain parasitic capacitance and to further suppress the deterioration of the characteristics.

(8) In the above (7), the semiconductor device further may include a connection wiring that electrically connects the third gate electrode to the gate wiring between the first transistor unit and the third transistor unit. A part of the first cover metal layer may overlap with at least a part of the connection wiring in plan view. This makes it possible to further suppress the gate-drain parasitic capacitance and to further suppress the deterioration of the characteristics.

(9) In any one of the above (1) to (8), the semiconductor device further may include a first drain wiring provided on the first drain electrode in electrical contact with the first drain electrode, a height from the substrate to an upper surface of the first drain wiring being smaller than a height from the substrate to an upper surface of the first cover metal layer; and a second drain wiring provided on the second drain electrode in electrical contact with the second drain electrode, a height from the substrate to an upper surface of the second drain wiring being smaller than a height from the substrate to an upper surface of the second cover metal layer. This makes it possible to suppress the gate-drain parasitic capacitance and the gate-source parasitic capacitance, and to suppress the deterioration of the characteristics.

(10) A semiconductor device according to the present disclosure includes: a substrate; a first transistor unit having a first drain electrode, a first gate electrode, and a first source electrode which are provided in order on the substrate; a second transistor unit having a second source electrode arranged along the first source electrode and electrically connected to the first source electrode, a second gate electrode electrically connected to the first gate electrode, and a second drain electrode electrically connected to the first drain electrode, the second source electrode, the second gate electrode and the second drain electrode being provided in order on the substrate, the second transistor unit being located in a direction where the first drain electrode, the first gate electrode, and the first source electrode are arranged with respect to the first transistor unit; a gate wiring provided on the substrate between the first source electrode and the second source electrode and adjacent to the first source electrode and the second source electrode, and electrically connected to the first gate electrode and the second gate electrode; a first source wiring provided on the first source electrode in electrical contact with the first source electrode; a second source wiring provided on the second source electrode in electrical contact with the second source electrode; a first drain wiring provided on the first drain electrode in electrical contact with the first drain electrode, a height of an upper surface of the first drain wiring from the substrate being smaller than a height of an upper surface of the first source wiring from the substrate; and a second drain wiring provided on the second drain electrode in electrical contact with the second drain electrode, and a height of an upper surface of the second drain wiring from the substrate being smaller than a height of an upper surface of the second source wiring from the substrate. This makes it possible to suppress the gate-drain parasitic capacitance and the gate-source parasitic capacitance, and to suppress the deterioration of the characteristics.

(11) In the above (10), the semiconductor device further may include: a third transistor unit having a third drain electrode electrically connected to the first drain electrode, a third gate electrode electrically connected to the gate wiring, and a third source electrode electrically connected to the first source electrode. The third drain electrode, the third gate electrode and the third source electrode may be provided in order on the substrate. The third transistor unit may be located in a direction where the first gate electrode extends with respect to the first transistor unit. This makes it possible to further suppress the gate-drain parasitic capacitance and to further suppress the deterioration of the characteristics.

Specific examples of a semiconductor device according to embodiments of the present disclosure will be described below with reference to the drawings. It should be noted that the present disclosure is not limited to these examples, but is defined by the claims and is intended to include all modifications within the meaning and scope equivalent to the claims.

### First Embodiment

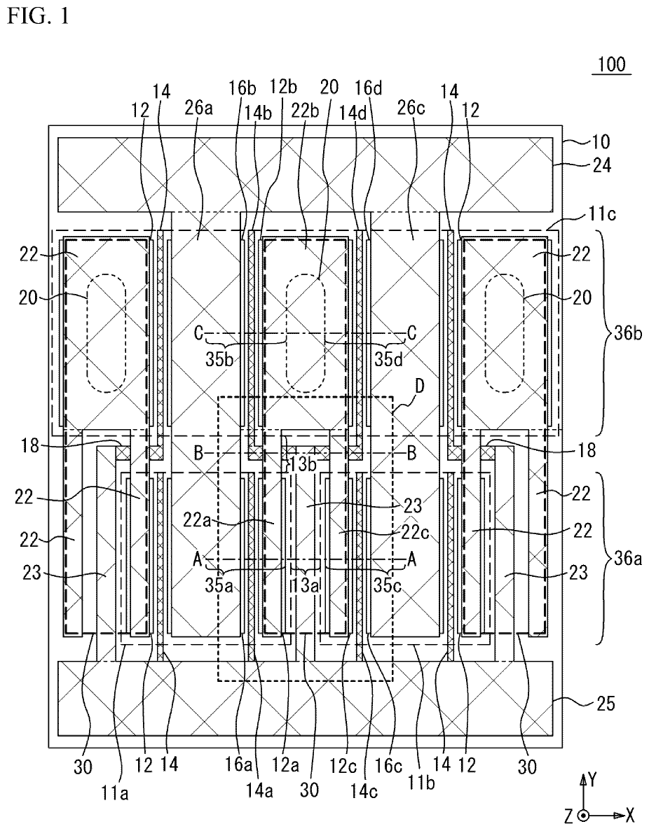

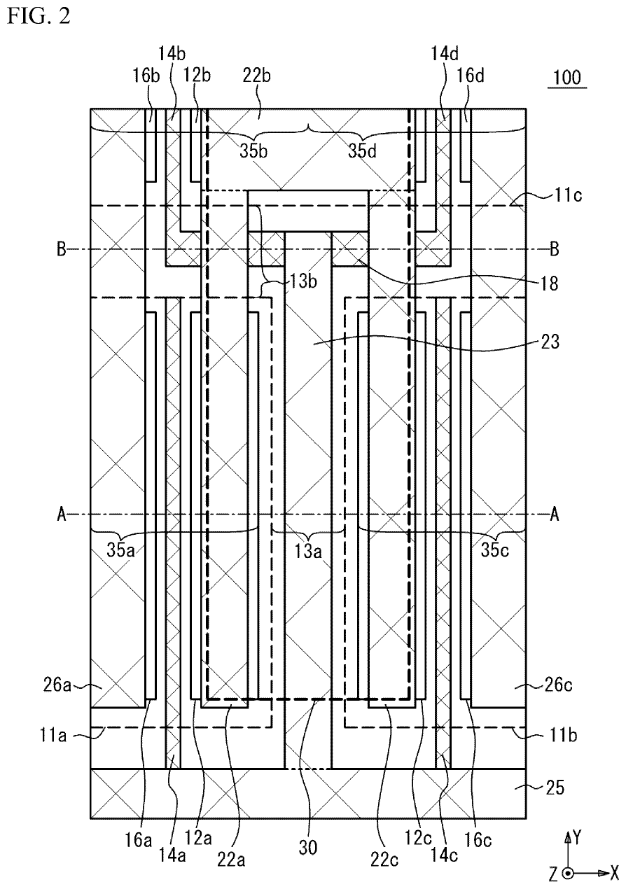

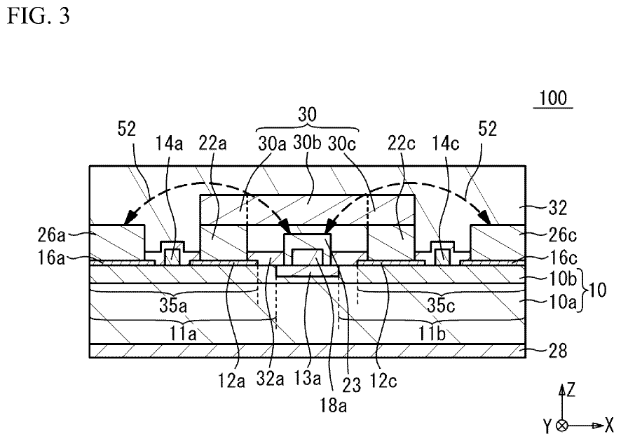

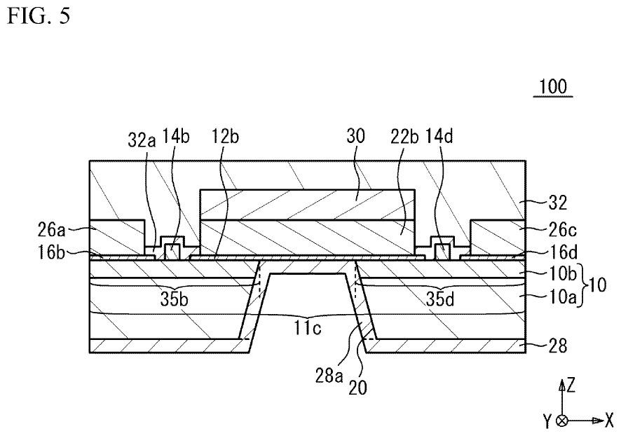

A description will be given of a semiconductor device used in an amplifier for amplifying a high frequency signal of, for example, 0.5 GHz to 10 GHz in a base station of mobile communication as an example. FIG. 1 is a plan view of a semiconductor device according to a first embodiment. FIG. 2 is an enlarged view of a range D in FIG. 1, and FIGS. 3 to 5 are cross-sectional views taken along lines A-A, B-B and C-C of FIG. 1 or FIG. 2, respectively. A thickness direction of a substrate 10 is defined as a Z direction, an extending direction of finger-shaped electrodes is defined as a Y direction (first direction), and an arrangement direction of the electrodes is defined as an X direction (second direction intersecting the first direction). In the plan views of FIGS. 1 and 2, it is difficult to see a cover metal layer 30 and source wirings 22a to 22c when they overlap with each other. Therefore, a thick broken line illustrating only the outer periphery of the cover metal layer 30 is illustrated inside the source wirings 22a to 22c when the cover metal layer 30 is seen through.

In each figure, a source electrode 12, a gate electrode 14, a source wiring 22 and a unit FET 35 represent general elements. Source electrodes 12a to 12c, gate electrodes 14a to 14d, the source wirings 22a to 22c and unit FETs 35a to 35d represent specific elements included in the general elements. In the following, the unit FETs 35 a to 35d will be mainly described by using the source electrodes 12a to 12c, the gate electrodes 14a to 14d, drain electrodes 16a and 16b, the source wirings 22a to 22c, and drain wirings 26a and 26c.

As illustrated in FIGS. 1 to 5, in a semiconductor device 100 of the first embodiment, the substrate 10 includes a substrate 10a and a semiconductor layer 10b provided on the substrate 10a. In an XY plane parallel to the X direction and the Y direction, regions of the semiconductor layer 10b deactivated by ion implantation or the like are inactive regions 13a and 13b, and regions not inactivated are active regions 11a to 11c.

The active regions 11a and 11b are arranged in the X direction. The active region 11c is provided in a region in the +direction of the Y direction away from the active regions 11a and 11b. A region between the active regions 11a and 11b is the inactive region 13a. A region between the active region 11c and the active regions 11a and 11b is the inactive region 13b. An FET group 36a including the plurality of unit FETs 35a and 35c arranged in the X direction is provided on the active regions 11a and 11b. An FET group 36b including the plurality of unit FETs 35b and 35d arranged in the X direction is provided on the active region 11c. A gate bus bar 25 and the FET group 36b interpose the FET group 36a. A drain bus bar 24 and the FET group 36a interpose the FET group 36b.

The unit FET 35a (first transistor unit) has the source electrode 12a (first source electrode), the gate electrode 14a (first gate electrode), and the drain electrode 16a (first drain electrode), which extend in the Y direction and are provided on the substrate 10. The drain electrode 16a, the gate electrode 14a and the source electrode 12a are provided in this order in the X direction. The unit FET 35c (second transistor unit) is located in a direction in which the drain electrode 16a, the gate electrode 14a, and the source electrode 12a are arranged with respect to the unit EET 35a. The unit FET 35c has the source electrode 12c (second source electrode), the gate electrode 14c (second gate electrode), and a drain electrode 16c (second drain electrode), which are respectively extended in the Y direction and provided on the substrate 10. The source electrode 12c, the gate electrode 14c and the drain electrode 16c are provided in this order in the X direction. The source electrode 12c is provided along and parallel to the source electrode 12a and electrically connected to the source electrode 12a via the source electrode 12b. The gate electrode 14c is electrically connected to the gate electrode 14a via the gate bus bar 25. The drain electrode 16c is electrically connected to the drain electrode 16a via the drain bus bar 24.

A gate wiring 23 extending in the Y direction is provided on a region of the substrate 10 located in the +X direction of the unit FET 35a. The gate wiring 23 is provided adjacent to the source electrodes 12a and 12c on the inactive region 13a between the unit FETs 35a and 35c. That is, in the unit FET 35a, the source electrode 12a is closer to the gate wiring 23 than the drain electrode 16a. In the unit FET 35c, the source electrode 12c is closer to the gate wiring 23 than the drain electrode 16c. A gate metal layer 18a is provided between the gate wiring 23 and the substrate 10. The gate metal layer 18a may not be provided.

The unit FETs 35b (third transistor units) and 35d are provided in regions on the substrate 10 located in a direction in which the gate electrode 14a extends with respect to the unit FETs 35a and 35c, respectively. The unit FET 35b has the source electrode 12b (third source electrode), the gate electrode 14b (third gate electrode), and the drain electrode 16b (third drain electrode), which are respectively extended in the Y direction and provided on the substrate 10. The drain electrode 16b, the gate electrode 14b and the source electrode 12b are provided in this order in the X direction. The drain electrode 16b is electrically connected to the drain electrode 16a. The gate electrode 14b is electrically connected to the gate wiring 23. The source electrode 12b is electrically connected to the source electrode 12a. The unit FET 35d has the source electrode 12b, the gate electrode 14d, and a drain electrode 16d, which extend in the Y direction and are provided on the substrate 10. The unit FETs 35b and 35d share the source electrode 12b. When viewed from the Y direction, the source electrodes 12a and 12c and the gate wiring 23 are provided so as to overlap with the source electrode 12b and to be included within a range where the source electrode 12b is provided.

A gate wiring 18 extending in the X direction is provided on the inactive region 13b. The gate wiring 18 electrically connects and short-circuits the gate wiring 23 to the gate electrodes 14b and 14d. The gate wiring 23 and the gate electrodes 14a and 14c are connected to the gate bus bar 25.

The source wirings 22a (first source wirings), 22b and 22c (second source wirings) are provided on the source electrodes 12a, 12b and 12c in contact therewith, respectively. The source wirings 22a and 22c interpose the gate wiring 18 and an insulating layer 32a, and intersect with the gate wiring 18 and the insulating layer 32a in a non-contact manner, and are connected to the source electrode 12b. The drain wiring 26a (first drain wiring) is provided on the drain electrodes 16a and 16b in contact therewith, and electrically connects the drain electrodes 16a and 16b to the drain bus bar 24. The drain wiring 26c (second drain wiring) is provided on the drain electrodes 16c and 16d in contact therewith, and electrically connects the drain electrodes 16c and 16d to the drain bus bar 24.

The cover metal layer 30 is provided on the source wirings 22a to 22c in contact therewith. The insulating layer 32 is provided on the substrate 10 so as to cover the source electrodes 12a to 12c, the gate electrodes 14a to 14d, the drain electrodes 16a to 16d, the source wirings 22a to 22c, the drain wirings 26a and 26c, and the cover metal layer 30. The cover metal layer 30 is provided so as to overlap with a part of the gate wiring 18 and a part of the gate wiring 23 when viewed from the Z direction. As illustrated in FIG. 3, in the FET group 36a, the cover metal layer 30 includes metal layers 30a and 30c provided on the source wirings 22a and 22c, respectively, and a metal layer 30b connecting the metal layers 30a and 30c. The metal layers 30a to 30c are provided integrally and continuously.

Via holes 20 penetrate the substrate 10 and are connected to the source electrode 12b. A metal layer 28 is provided on the lower surface of the substrate 10. A metal layer 28a is provided on the inner surface of the via hole 20. As a result, the metal layer 28 is electrically connected and short-circuited to the source electrode 12b through the via hole 20.

A source potential (for example, a reference potential such as a ground potential) is supplied from the metal layer 28 to the source electrode 12b through the metal layer 28a in the via hole 20. Further, the source potential is supplied to the source electrodes 12a to 12c and the cover metal layer 30 through the source wirings 22a to 22c. A gate potential (e.g., a high frequency signal and a gate bias voltage) is supplied from the gate bus bar 25 to the gate electrodes 14a and 14c. The gate potential is supplied from the gate bus bar 25 to the gate electrodes 14b and 14d through the gate wirings 23 and 18. A drain bias voltage is supplied from the drain bus bar 24 to the drain electrodes 16a to 16d through the drain wirings 26a and 26c. High frequency signals amplified in the respective unit FETs 35a to 35d are output from the drain wirings 26a and 26c to the drain bus bar 24.

In the unit FETs 35a and 35c, the high frequency signals are input from the − ends of the gate electrodes 14a and 14c in the Y direction. In the unit FETs 35b and 35d, the high frequency signals are input from the − ends of the gate electrodes 14b and 14d in the Y direction. When the high frequency signals are inputted to the gate electrodes 14a and 14c from both ends of the + end and the − end of the gate electrodes 14a and 14c in the Y direction, the high frequency characteristics of the unit FETs 35a and 35c are deteriorated due to the phase difference or the like. In the first embodiment, since the + ends of the gate electrodes 14a and 14c in the Y direction and the − ends of the gate electrodes 14b and 14d in the Y direction are not connected to each other, the deterioration of the high frequency characteristics of the unit FETs 35a and 35c can be suppressed.

When the semiconductor device 100 is, for example, a nitride semiconductor device, the substrate 10a is, for example, a silicon carbide (SiC) substrate, a silicon (Si) substrate, a gallium nitride (GaN) substrate, or a sapphire (Al₂O₃) substrate. The semiconductor layer 10b includes a nitride semiconductor layer such as a gallium nitride layer, an aluminum gallium nitride (AlGaN) layer, and/or an indium gallium nitride (InGaN) layer. When the unit FETs 35a to 35d are GaN HEMTs (Gallium Nitride High Electron Mobility Transistors), the semiconductor layer 10b includes a gallium nitride channel layer provided on the substrate 10a and an aluminum gallium nitride barrier layer provided on the channel layer. When the semiconductor device 100 is, for example, a gallium arsenide (GaAs)-based semiconductor device, the substrate 10a is, for example, a gallium arsenide substrate. The semiconductor layer 10b includes an arsenide semiconductor layer, such as a gallium arsenide layer, an aluminum gallium arsenide (AlGaAs) layer and/or an indium gallium arsenide (InGaAs) layer. The semiconductor device 100 may be a silicon semiconductor device such as a LDMOS (Laterally Diffused Metal Oxide Semiconductor).

The source electrodes 12a to 12c and the drain electrodes 16a to 16d are metal films, and for example, include a titanium film and an aluminum film stacked on the substrate 10 in this order. The gate electrodes 14a to 14d and the gate metal layer 18a are metal films, and for example, include a nickel film and a gold film stacked on the substrate 10 in this order. The source wirings 22a to 22c, the drain wirings 26a and 26c, the gate wiring 23, and the cover metal layer 30 are, for example, gold layers, copper layers, or aluminum layers. The insulating layer 32a is an inorganic insulating layer such as a silicon nitride layer. An insulating layer 32 is an organic insulating layer such as a polyimide layer or a BCB (Benzocyclobutane) layer.

The widths of the source electrodes 12a and 12c in the X direction are, for example, 5 μm to 20 μm. The width of the source electrode 12b in the X direction is, for example, 50 μm to 150 μm. The gate lengths of the gate electrodes 14a to 14d in the X direction are, for example, 0.25 μm to 2 μm. The widths of the drain electrodes 16a and 16c in the X direction are, for example, 5 μm to 150 μm. The width of the gate wiring 23 in the X direction is, for example, 5 μm to 20 μm. The width of the gate wiring 18 in the Y direction is, for example, 3 μm to 20 μm. The gate widths of the unit FETs 35a to 35d in the Y direction are, for example, 100 μm to 400 μm. The width of the via hole 20 in the X direction is, for example, 10 μm to 60 μm.

The widths of the source wirings 22a to 22c and the drain wirings 26a and 26c in the X direction are equal to or slightly smaller than the widths of the source electrodes 12a to 12c and the drain electrodes 16a and 16c in the X direction, respectively. The thicknesses of the source wirings 22a to 22c and the drain wirings 26a and 26c are, for example, 1 μm to 20 μm. The thickness of the gate wiring 23 is, for example, 0.5 μm to 5 μm. The thickness of the gate wiring 23 may be the same as or smaller than the thicknesses of the source wirings 22a to 22c and the drain wirings 26a and 26c. The thickness of the cover metal layer 30 is, for example, 1 μm to 5 μm.

### [Manufacturing Method of First Embodiment]

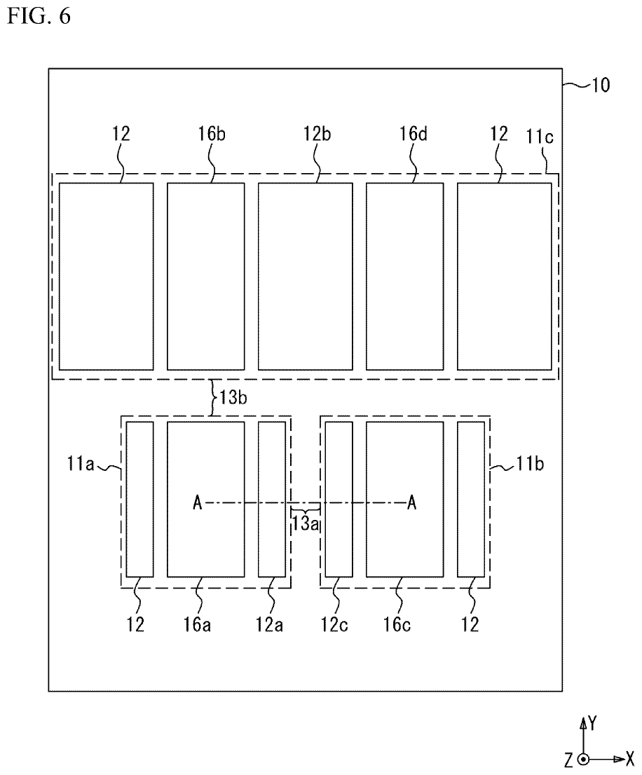

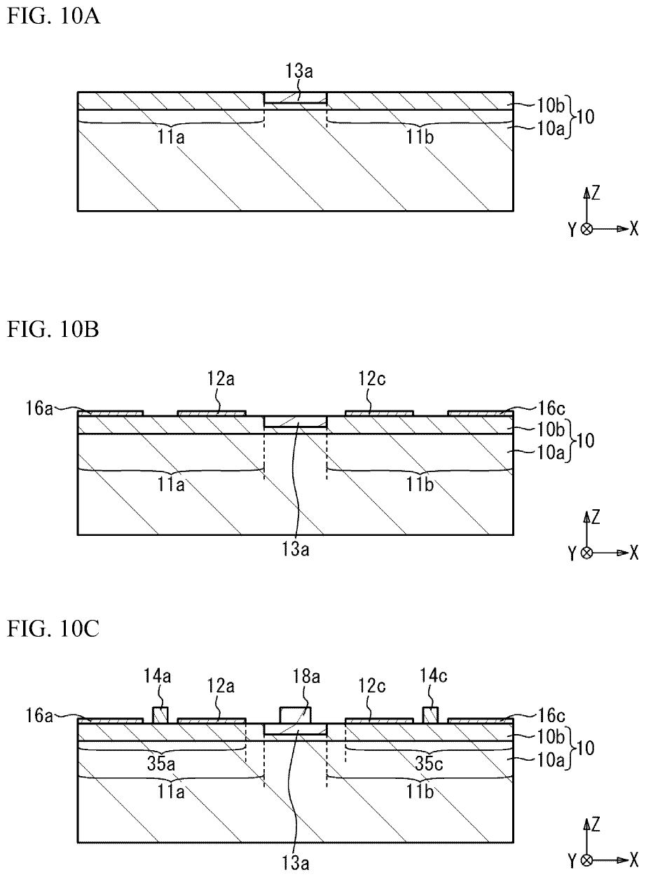

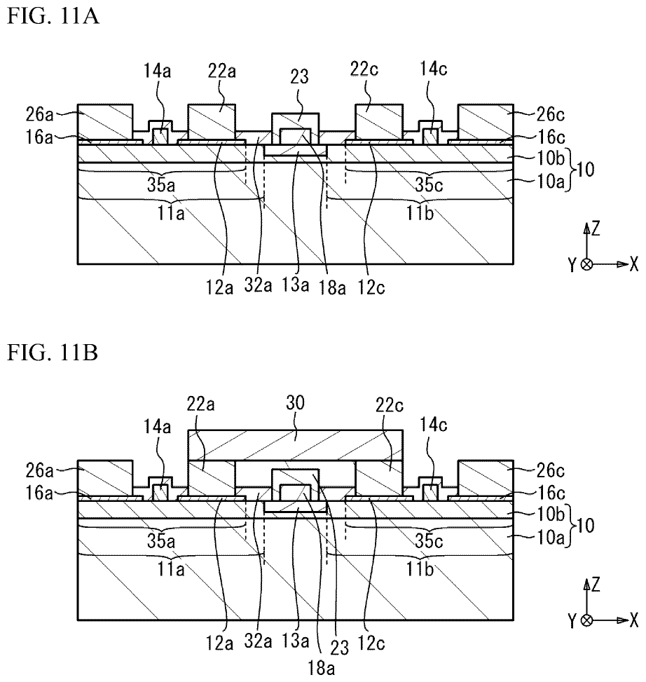

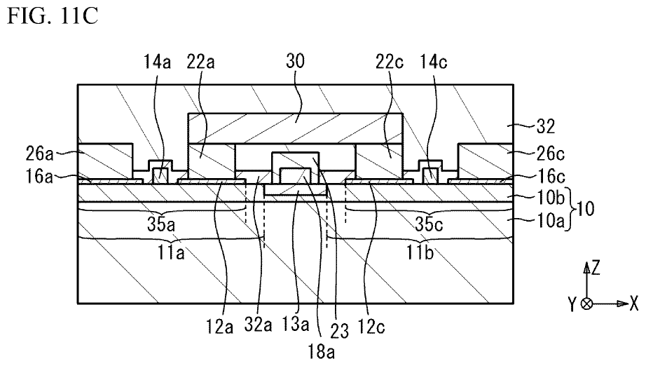

FIGS. 6 to 9 are plan views illustrating a method of manufacturing the semiconductor device according to the first embodiment. FIGS. 10A to 11C are cross-sectional views illustrating a method of manufacturing the semiconductor device according to the first embodiment, and correspond to the A-A cross-section of FIGS. 6 to 9.

As illustrated in FIGS. 6 and 10A, the semiconductor layer 10b is ion-implanted to form the inactive regions 13a and 13b in the semiconductor layer 10b. Regions where the inactive regions 13a and 13b are not formed are the active regions 11a to 11c. The inactive region 13a is formed between the active regions 11a and 11b, and the inactive region 13b is formed between the active regions 11a and 11b and the active region 11c.

As illustrated in FIGS. 6 and 10B, the source electrode 12a and the drain electrode 16a are formed on the active region 11a. The source electrode 12c and the drain electrode 16c are formed on the active region 11b. The source electrode 12b and the drain electrodes 16b and 16d are formed on the active region 11c. The source electrodes 12a to 12c and the drain electrodes 16a to 16d are formed by, for example, a vacuum evaporation method and a lift-off method. The resultant structure is then subjected to heat treatment. As a result, the source electrodes 12a to 12c and the drain electrodes 16a to 16d are in ohmic contact with the active regions 11a, 11b and 11c.

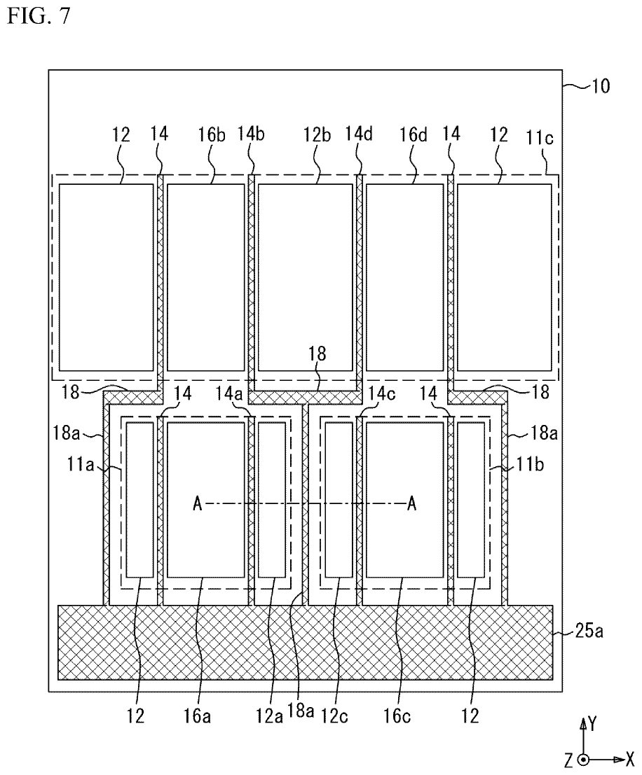

As illustrated in FIGS. 7 and 10C, the gate electrodes 14a to 14d, the gate wiring 18, and the gate metal layers 18a and 25a are formed on the substrate 10. The gate electrodes 14a to 14d, the gate wiring 18, and the gate metal layers 18a and 25a are formed by, for example, the vacuum evaporation method and the lift-off method.

As illustrated in FIG. 11A, the insulating layer 32a is formed on the substrate 10 so as to cover the source electrodes 12a to 12c, the drain electrodes 16a and 16c, the gate electrodes 14a to 14d, the gate wiring 18, and the gate metal layers 18a and 25a. The insulating layer 32a is formed by, for example, a CVD (Chemical Vapor Deposition) method.

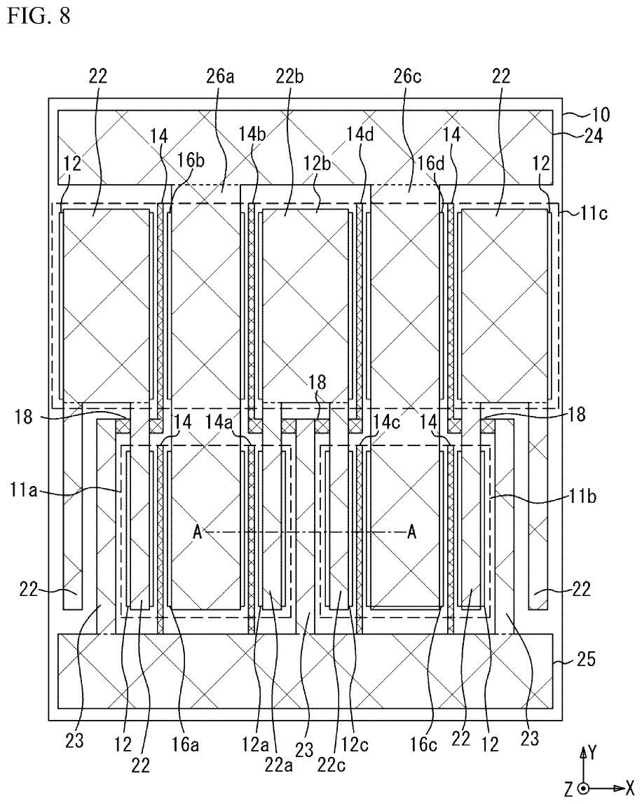

As illustrated in FIGS. 8 and 11A, openings are formed at desired regions of the insulating layer 32a by an etching method. The source wirings 22a to 22c and the drain wirings 26a and 26c are formed on the source electrodes 12a to 12c and the drain electrodes 16a and 16c, respectively. The gate wiring 23 is formed on the gate metal layer 18a. The gate bus bar 25 and the drain bus bar 24 are formed. The source wirings 22a to 22c, the drain wirings 26a and 26c, the gate wiring 23, the gate bus bar 25, and the drain bus bar 24 are formed by, for example, a plating method.

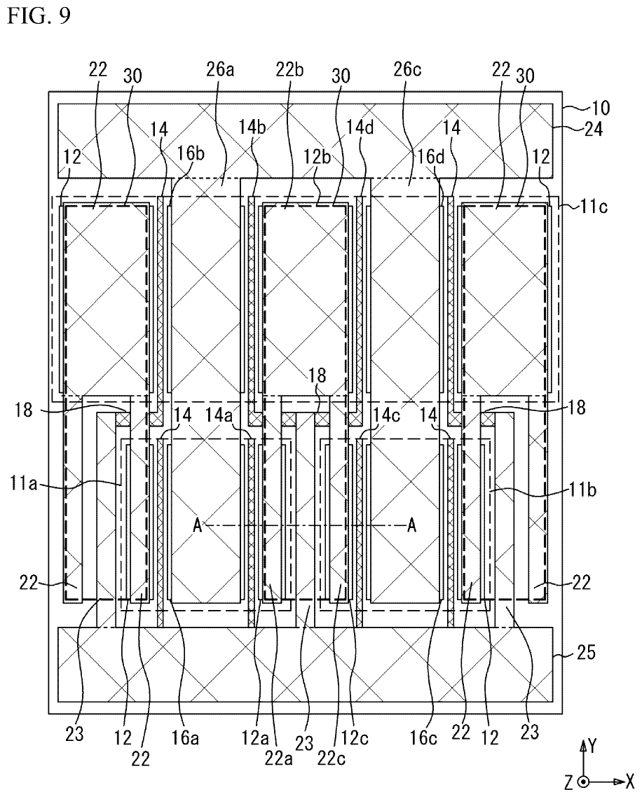

As illustrated in FIGS. 9 and 11B, the cover metal layer 30 is formed on the source wirings 22a to 22c. The cover metal layer 30 is formed by the plating method, for example. A space between the source wirings 22a and 22c is covered with the cover metal layer 30. As illustrated in FIG. 11C, the insulating layer 32 is formed on the substrate 10 so as to cover the source wirings 22a to 22c, the drain wirings 26a and 26c, the gate wiring 23, and the cover metal layer 30. The insulating layer 32 is formed in the space surrounded by the source wirings 22a and 22c and the cover metal layer 30. The insulating layer 32 includes, for example, an inorganic insulating layer and an organic insulating layer formed on the inorganic insulating layer. The inorganic insulator layer is formed by, for example, the CVD method. The organic insulating layer is formed by applying a solvent containing a resin and performing heat treatment. Openings (not illustrated) are formed in the insulating layer 32 to expose the gate bus bar 25 and the drain bus bar 24.

Thereafter, the lower surface of the substrate 10 is thinned by polishing or grinding, and the via holes 20 penetrating the substrate 10 are formed. The metal layers 28 and 28a are formed on the lower surface of the substrate 10 and the inner surface of the via holes 20. Thus, the semiconductor device according to the first embodiment is manufactured.

### First Comparative Example

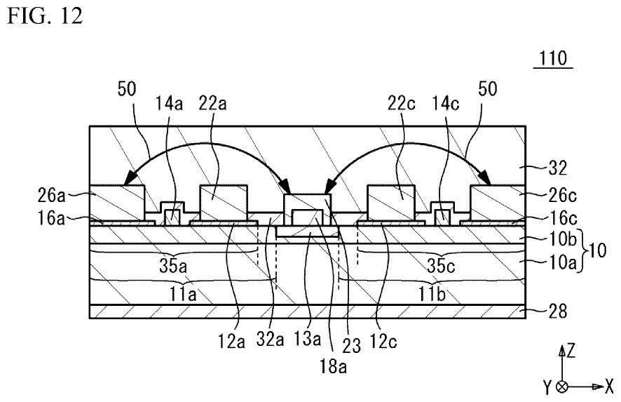

FIG. 12 is a cross-sectional view of a semiconductor device according to a first comparative example. As illustrated in FIG. 12, a semiconductor device 110 of the first comparative example is not provided with the cover metal layer 30. The other configurations of the first comparative example are the same as those of the first embodiment.

The gate wirings 23 and 18 electrically connect the gate electrodes 14b and 14d to the gate bus bar 25. This makes it possible to lower the gate resistance of the unit FETs 35b and 35d. However, as indicated by solid line arrows 50, the gate wiring 23 and the drain wirings 26a and 26c are capacitively coupled by the lines of electric force passing over the source wirings 22a and 22c. This increases the gate-drain parasitic capacitance. As the gate-drain parasitic capacitance increases, the gain decreases. In addition, the K-factor, which is a stability coefficient, is lowered. In this way, the high frequency characteristics of the semiconductor device 110 deteriorate.

### [Description of First Embodiment]

As illustrated in FIG. 3, according to the first embodiment, the cover metal layer 30 is provided on the source wirings 22a and 22c and covers the entire space between the source wirings 22a and 22c. As a result, the cover metal layer 30 shields the lines of electric force between the gate wiring 23 and the drain wirings 26a and 26c as indicated by broken line arrows 52. This suppresses the capacitive coupling between the gate wiring 23 and the drain wirings 26a and 26c. Therefore, the gate-drain parasitic capacitance can be suppressed, and the deterioration of the high frequency characteristics of the semiconductor device 100 can be suppressed. In the first embodiment, the gate-source parasitic capacitance and the drain-source parasitic capacitance increase. However, the gate-source capacitance and the drain-source capacitance are larger than the gate-drain capacitance. Therefore, the influences of the gate-source parasitic capacitance and the drain-source parasitic capacitance are small.

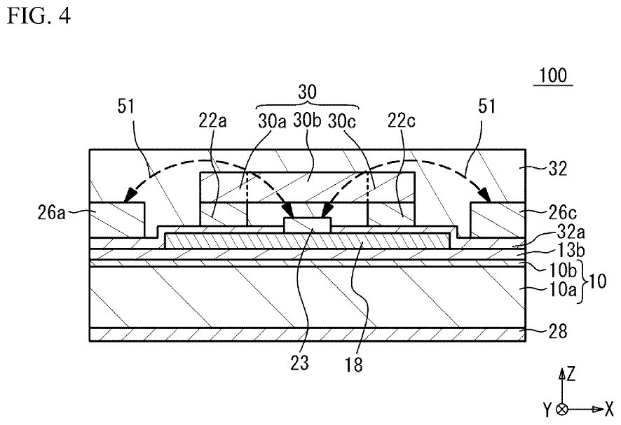

As illustrated in FIG. 4, in the inactive region 13b, the cover metal layer 30 is provided on the gate wiring 18 with the insulating layer 32a interposed therebetween. As a result, as indicated by broken line arrows 51, the cover metal layer 30 shields the lines of electric force between the gate wiring 18 and the drain wirings 26a and 26c, and suppresses the capacitive coupling. Therefore, the gate-drain parasitic capacitance can be suppressed, and the deterioration of the high frequency characteristics of the semiconductor device 100 can be suppressed.

### First Modification of First Embodiment

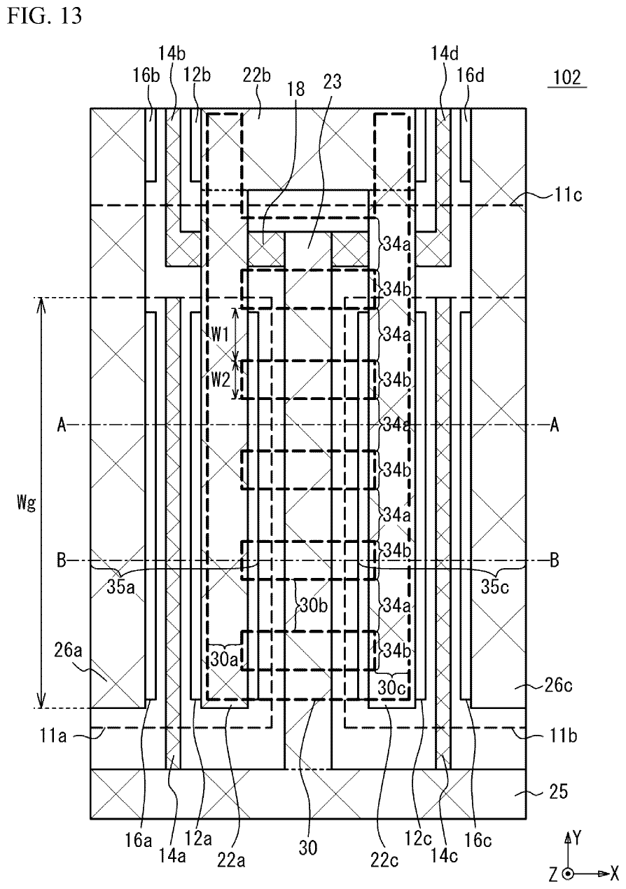

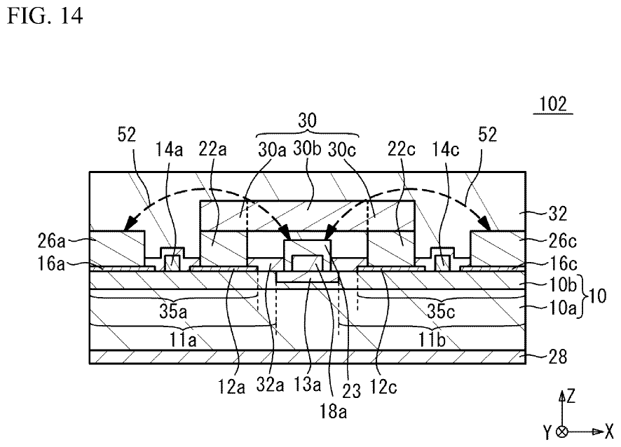

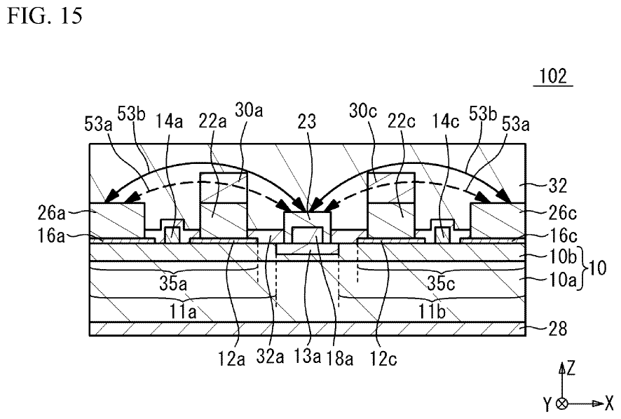

FIG. 13 is an enlarged plan view of a semiconductor device according to a first modification of the first embodiment. FIGS. 14 and 15 are cross-sectional views taken along a line A-A and a line B-B of FIG. 13, respectively. As illustrated in FIGS. 13 to 15, in a semiconductor device 102 of the first modification of the first embodiment, portions 34a where the metal layer 30b is provided and portions 34b where the metal layer 30b is not provided are alternately provided in the Y direction. The other configurations of the first modification of the first embodiment are the same as those of the first embodiment, and the description thereof is omitted.

As illustrated in FIG. 14, at the portions 34a where the metal layer 30b is provided, the metal layer 30b shields the lines of electric force between the gate wiring 23 and the drain wirings 26a and 26c as indicated by the broken line arrows 52, thereby suppressing the capacitive coupling. This suppresses the gate-drain parasitic capacitance. However, the gate-source parasitic capacitance between the gate wiring 23 and the metal layer 30b increases.

As illustrated in FIG. 15, in the portions 34b where the metal layer 30b is not provided, the metal layers 30a and 30c shield a part of the line of electric force between the gate wiring 23 and the drain wiring 26a and 26c as indicated by broken line arrows 53a. As indicated by solid arrows 53b, a part of the lines of electric force between the gate wiring 23 and the drain wirings 26a and 26c is not shielded. This increases the gate-drain parasitic capacitance compared with the first embodiment. However, since the metal layer 30b does not cover the upper portion of the gate wiring 23 at the portions 34b, the gate-source parasitic capacitance is reduced. This makes it possible to suppress the gate-source parasitic capacitance in the first modification of the first embodiment more than that in the first embodiment.

The number of the portions 34a and 34b and the widths W1 and W2 of the portions 34a and 34b in the Y direction can be appropriately set depending on whether the gate-drain parasitic capacitance or the gate-source parasitic capacitance is considered important. When importance is attached to the suppression of the gate-drain parasitic capacitance, the total of the widths W1 of the portions 34a in the Y direction can be set to 0.5 times or more or 0.7 times or more the gate width Wg (the widths of the active regions 11a and 11b in the Y direction) of the unit FETs 35a and 35c in the Y direction. When importance is attached to the suppression of the gate-source parasitic capacitance, the total of the widths W1 can be set to 0.5 times or less or 0.3 times or less the gate width Wg. Each of the widths W1 and W2 is, for example, 1 μm or more and 100 μm or less.

In the first embodiment, when the insulating layer 32 is provided in FIG. 11C, the solvent containing the resin may not flow around under the metal layer 30b, and voids may be formed. In the first modification of the first embodiment, the metal layer 30b is not provided at the portions 34b. Therefore, the solvent containing the resin flows around under the metal layer 30b at the portions 34a. Therefore, it is possible to suppress the formation of voids in the insulating layer 32.

### Second Modification of First Embodiment

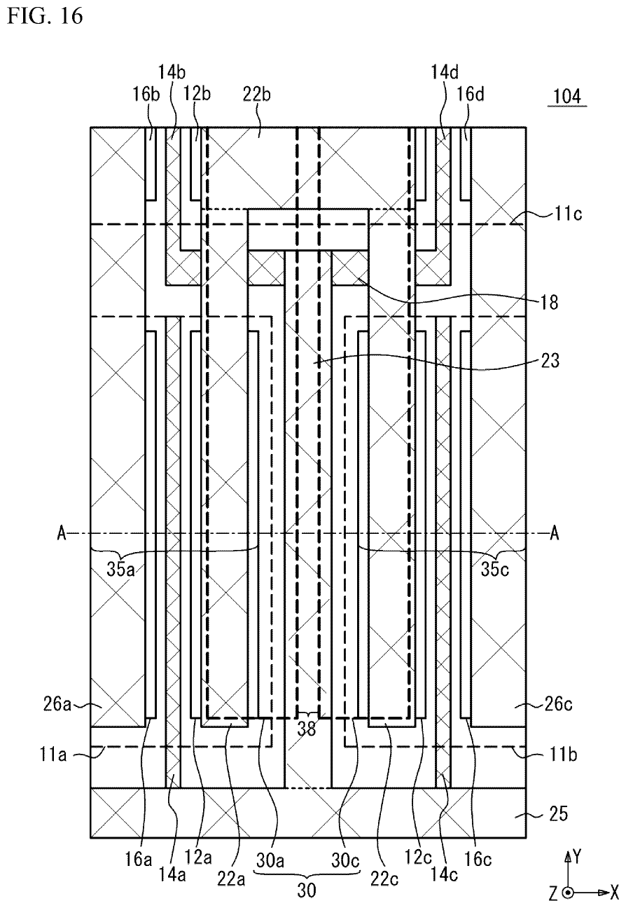

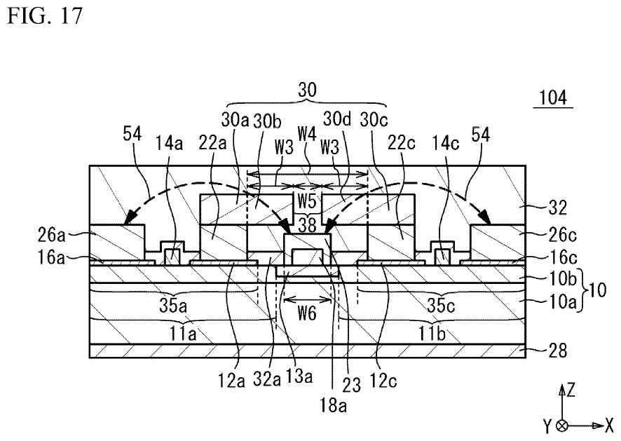

FIG. 16 is an enlarged plan view of a semiconductor device according to a second modification of the first embodiment. FIG. 17 is a cross-sectional view taken along a line A-A in FIG. 16. As illustrated in FIGS. 16 and 17, in a semiconductor device 104 of the second modification of the first embodiment, the cover metal layer 30 has metal layers 30a to 30d. The metal layers 30a and 30c are provided on the source wirings 22a and 22c in contact therewith, respectively. The metal layer 30b protrudes from the metal layer 30a toward the source wiring 22c. The metal layer 30d protrudes from the metal layer 30c toward the source wiring 22a. A gap 38 is provided between the metal layers 30b and 30d. When viewed from the Z direction, the +side surface of the metal layer 30b in the X direction overlaps with the gate wiring 23, and the − side surface of the metal layer 30d in the X direction overlaps with the gate wiring 23. The other configurations of the second modification of the first embodiment are the same as those of the first embodiment, and the description thereof is omitted.

As indicated by broken line arrows 54 in FIG. 17, most of the lines of electric force between the gate wiring 23 and the drain wirings 26a and 26c are shielded by the cover metal layer 30. Few lines of electric force pass through the gap 38. Therefore, the gate-drain parasitic capacitance can be suppressed. On the other hand, a part of the region of the cover metal layer 30 closest to the gate wiring 23 is the gap 38. This can suppress the gate-source parasitic capacitance.

The width W3 of the metal layers 30b and 30d in the X direction can be set appropriately depending on whether the gate-drain parasitic capacitance or the gate-source parasitic capacitance is considered important. When importance is attached to the suppression of the gate-drain parasitic capacitance, each of widths W3 of the metal layers 30b and 30d in the X direction can be set to 0.25 times or more or 0.4 times or more an interval W4 between the source wirings 22a and 22c in the X direction. When importance is attached to the suppression of the gate-source parasitic capacitance, each of the widths W3 can be set to 0.4 times or less or 0.25 times or less the interval W4.

A width W5 of the gap 38 in the X direction can be set appropriately depending on whether the gate-drain parasitic capacitance or the gate-source parasitic capacitance is considered important. When importance is attached to the suppression of the gate-drain parasitic capacitance, the width W5 can be 0.8 times or less or 0.5 times or less a width W6 of the gate wiring 23 in the X direction. When importance is attached to the suppression of the gate-source parasitic capacitance, the width W5 can be 0.5 times or more or 0.8 times or more the width W6. When viewed from the Z direction, the +side surface of the metal layer 30b in the X direction may not overlap with the gate wiring 23, and the − side surface of the metal layer 30d in the X direction may not overlap with the gate wiring 23.

When the insulating layer 32 is provided in FIG. 11C, the solvent containing the resin passes through the gap 38 and flows around under the metal layers 30b and 30d. Therefore, it is possible to suppress the formation of voids in the insulating layer 32.

In the first embodiment and the first and second modifications thereof, the cover metal layer 30 is flat, but the central portion of the cover metal layer 30 in the X direction may be arched so as to bulge upward.

### Third Modification of First Embodiment

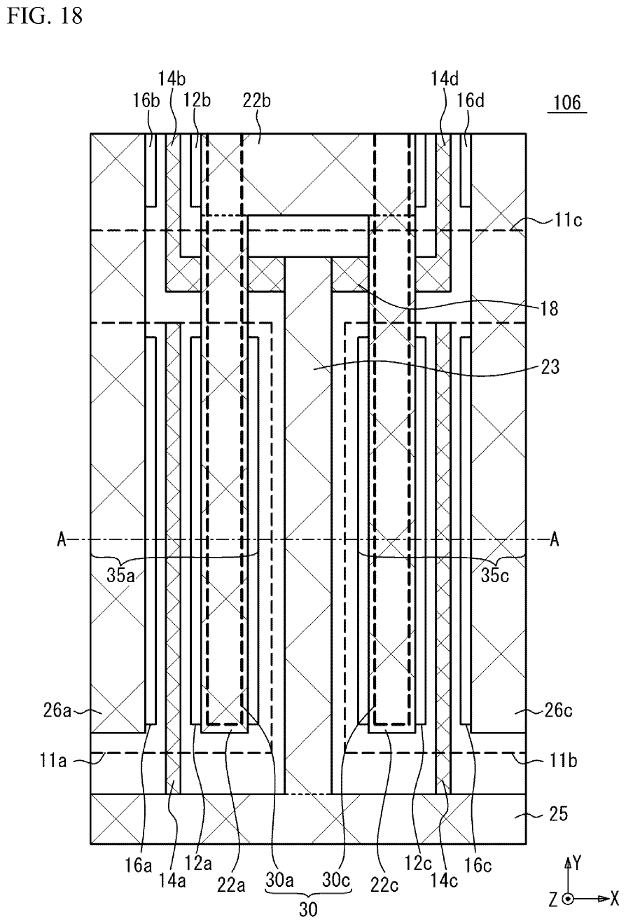

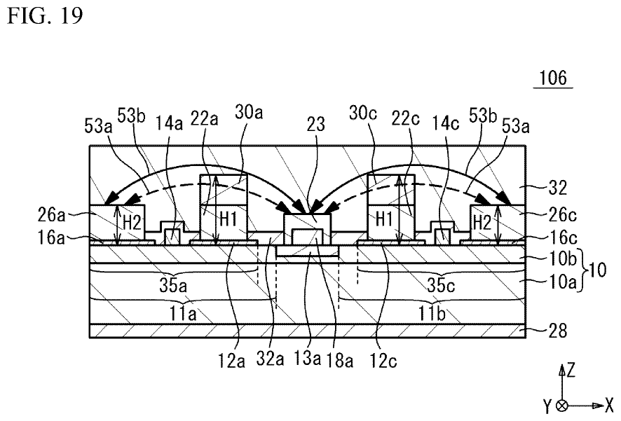

FIG. 18 is an enlarged plan view of a semiconductor device according to a third modification of the first embodiment. FIG. 19 is a cross-sectional view taken along a line A-A in FIG. 18. As illustrated in FIGS. 18 and 19, in a semiconductor device 106 of the third modification of the first embodiment, the cover metal layer 30 has the metal layers 30a and 30c. The metal layers 30a and 30c are provided on the source wirings 22a and 22c in contact therewith, respectively. The cover metal layer 30 is not provided between the source wirings 22a and 22c. The other configurations of the third modification of the first embodiment are the same as those of the first embodiment, and the description thereof is omitted.

As illustrated in FIG. 19, the metal layers 30a and 30c shield a part of the lines of electric force between the gate wiring 23 and the drain wiring 26a and 26c as indicated by the broken line arrows 53a. As indicated by the solid arrows 53b, a part of the lines of electric force between the gate wiring 23 and the drain wirings 26a and 26c is not shielded. This increases the gate-drain parasitic capacitance compared with the first embodiment and decreases the gate-source parasitic capacitance.

From the viewpoint of suppressing the gate-drain parasitic capacitance, a height H1 of the upper surfaces of the metal layers 30a and 30c from the upper surface of the substrate 10 can be 1.5 times or more, 2.5 times or more, or 3 times or more a height H2 of the upper surfaces of the drain wirings 26a and 26c from the upper surface of the substrate 10. From the viewpoint of the manufacturing process, the height H1 can be set to be 10 times or less the height H2. In the first embodiment and the first and second modifications thereof, the height H1 may be larger than the height H2, and may be 1.5 times or more, 2.5 times or more, or 3 times or more the height H2.

According to the first embodiment and the first and second modifications thereof, as illustrated in FIGS. 3, 14 and 17, the metal layers 30a and 30b (first cover metal layer) of the cover metal layer 30 are provided on the source wiring 22a in contact therewith and electrically connected to the source electrode 12a through the source wiring 22a. The metal layer 30b protrudes toward the gate wiring 23 more than the source electrode 12a. Thus, the projecting metal layer 30b suppresses the capacitive coupling between the gate wiring 23 and the drain wiring 26a. Therefore, the gate-drain parasitic capacitance can be suppressed, and the deterioration of the characteristics of the semiconductor device can be suppressed.

The metal layers 30c and 30d (second cover metal layer) of the cover metal layer 30 are provided on the source wiring 22c in contact therewith and electrically connected to the source electrode 12c via the source wiring 22c. The metal layer 30d protrudes toward the gate wiring 23 more than the source electrode 12c. Thus, the projecting metal layer 30d suppresses the capacitive coupling between the gate wiring 23 and the drain wiring 26c. Therefore, the gate-drain parasitic capacitance can be further suppressed, and the deterioration of the characteristics of the semiconductor device can be further suppressed. It is sufficient that at least the upper portion of the cover metal layer 30 protrudes toward the gate wiring 23 more than the source electrodes 12a and 12c.

At least a part of the cover metal layer 30 overlaps with the gate wiring 23 in a non-contact manner when viewed from the Z direction (that is, in plan view). This makes it possible to further suppress the gate-drain parasitic capacitance and to further suppress the deterioration of the characteristics of the semiconductor device.

According to the first embodiment and the first modification thereof, the metal layers 30b and 30c are in contact with each other above the gate wiring 23 as illustrated in FIGS. 3 and 14. This makes it possible to further suppress the gate-drain parasitic capacitance and to further suppress the deterioration of the characteristics of the semiconductor device.

As illustrated in FIGS. 2 and 3 of the first embodiment, the metal layer 30b may be provided in all regions between the metal layers 30a and 30c when viewed from the Z direction. This makes it possible to suppress the gate-drain parasitic capacitance and further suppress the deterioration of the characteristics of the semiconductor device.

As illustrated in FIG. 13 of the first modification of the first embodiment, the portions 34a where the metal layers 30b and 30c are in contact with each other above the gate wiring 23 and the portion 34b where the metal layers 30b and 30c are not provided above the gate wiring 23 are alternately provided along the gate wiring 23 in the Y direction. This makes it possible to set the gate-drain parasitic capacitance and the gate-source parasitic capacitance to desired values, and to further suppress deterioration of the characteristics of the semiconductor device.

As illustrated in FIGS. 16 and 17 of the second modification of the first embodiment, the metal layers 30b and 30d are not in contact with each other above the gate wiring 23. This makes it possible to suppress the gate-source parasitic capacitance and further suppress the deterioration of the characteristics of the semiconductor device.

The ends of the metal layers 30b and 30d in the X direction with overlap the gate wiring 23 when viewed from the Z direction. This makes it possible to suppress the gate-drain parasitic capacitance and the gate-source parasitic capacitance, and to further suppress the deterioration of the characteristics of the semiconductor device.

As illustrated in FIG. 4 of the first embodiment, the gate wiring 18 (connection wiring) extends in the X direction between the unit FETs 35a and 35b and electrically connects the gate electrode 14b and the gate wiring 23. A part of the cover metal layer 30 overlaps with at least a part of the gate wiring 18 when viewed from the Z direction. This suppresses the capacitive coupling between the gate wiring 23 and the drain wiring 26a. Therefore, the gate-drain parasitic capacitance can be further suppressed, and the deterioration of the characteristics of the semiconductor device can be further suppressed.

As illustrated in FIG. 19 of the third modification of the first embodiment, the height H2 of the drain wiring 26a from the substrate 10 is smaller than the heights of the source wiring 22a and the metal layer 30a from the substrate 10. This makes it possible to suppress the gate-drain parasitic capacitance and the gate-source parasitic capacitance, and to suppress the deterioration of the characteristics of the semiconductor device.

The height H2 of the drain wiring 26c from the substrate 10 is smaller than the height H1 of the source wiring 22c and the metal layer 30c from the substrate 10. This makes it possible to further suppress the gate-drain parasitic capacitance and the gate-source parasitic capacitance, and to further suppress the deterioration of the characteristics of the semiconductor device.

Although the cover metal layer 30 is provided on the source wiring 22b in the first embodiment and the modification thereof, the cover metal layer 30 may not be provided on the source wiring 22b. Although the source wirings 22a and 22c and the cover metal layer 30 are formed in separate steps as illustrated in FIGS. 8 and 9, the source wirings 22a and 22c and the cover metal layer 30 may be formed integrally at the same time.

### Second Embodiment

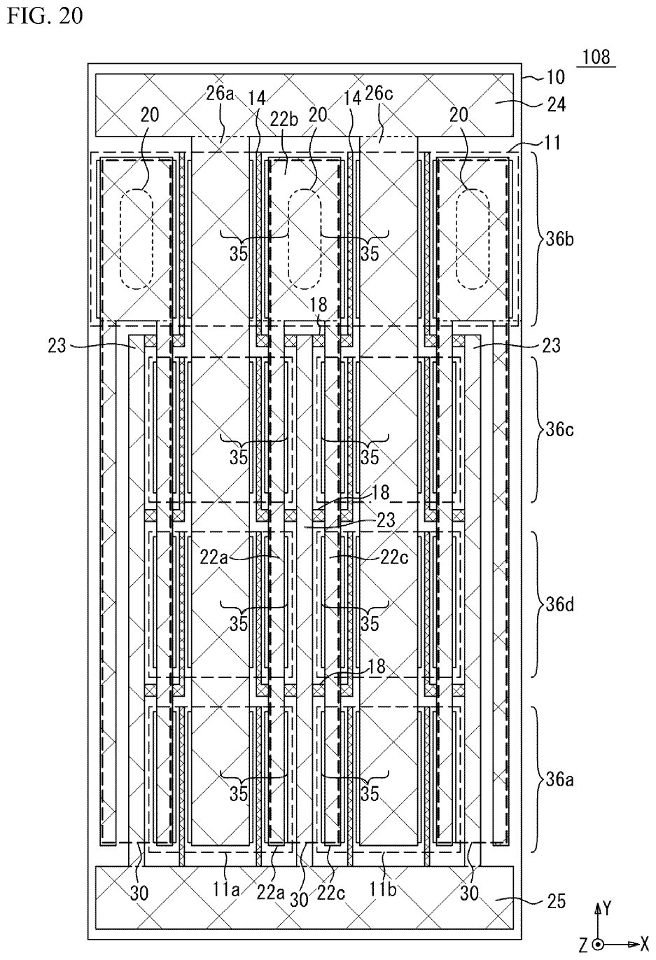

FIG. 20 is a plan view of a semiconductor device according to a second embodiment. As illustrated in FIG. 20, in a semiconductor device 108 of the second embodiment, FET groups 36c and 36d are provided between the FET groups 36a and 36b. The source wirings 22a and 22c are electrically connected to the source electrodes of the FET groups 36a, 36c and 36d. The drain wirings 26a and 26c are electrically connected to drain electrodes of the FET groups 36a to 36d. The gate wirings 18 and 23 are electrically connected to the gate electrodes 14 of the FET groups 36b to 36d. The cover metal layer 30 is provided in a region between the source wirings 22a and 22c of the FET groups 36a, 36c and 36d. The other configurations of the second embodiment are the same as those of the first embodiment, and the description thereof is omitted.

As in the second embodiment, the number of FET groups arranged in the Y direction may be four. In the first embodiment and the modification thereof, the number of FET groups arranged in the Y direction can be set as appropriate. Although the first and second embodiments and the modification thereof have been described with reference to the example in which the number of the unit FETs 35 in the X direction is four, the number of the unit FETs 35 in the X direction may be set to any one of one to three or five or more as appropriate.

### [Measurement Result]

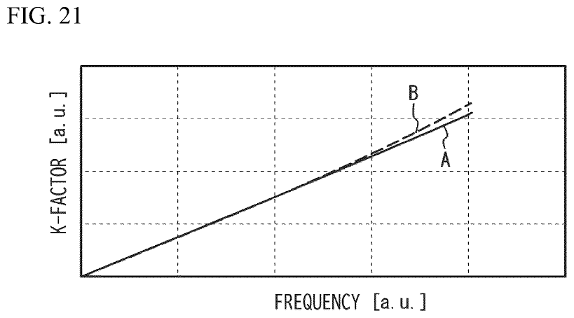

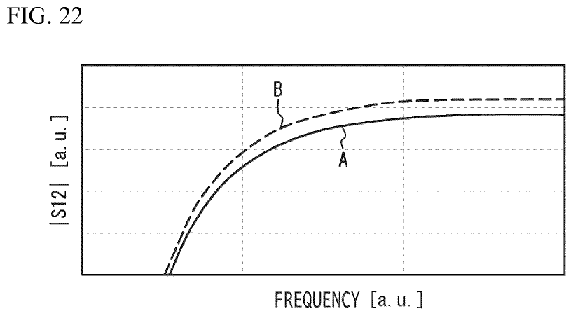

The GaN HEMTs having the structures of the first comparative example and the first modification of the first embodiment were fabricated, and the high frequency characteristics thereof were measured. A high frequency signal is input to the gate bus bar 25, and an amplified high frequency signal is output from the drain bus bar 24. FIG. 21 is a diagram illustrating a K-factor with respect to a frequency in semiconductor devices A and B. FIG. 22 is a diagram illustrating |S12| with respect to a frequency in the semiconductor devices A and B. In FIG. 21, a horizontal axis represents the frequency, and a vertical axis represents the K-factor which is a stability coefficient. The smaller the K-factor, the less likely the oscillation occurs and the more stable the oscillation is. In FIG. 22, a horizontal axis represents the frequency, and a vertical axis represents the |S12|. The |S12| is an absolute value of S-parameter S12 when the gate is a port 1 and the drain is a port 2. The |S12| represents a power fed back from the drain to the gate. The semiconductor device A corresponds to the first modification of the first embodiment, and the semiconductor device B corresponds to the first comparative example.

As illustrated in FIGS. 21 and 22, the K-factor and the |S12| increase as the frequency increases. The K-factor and the |S12| of the semiconductor device A are smaller than those of the semiconductor device B. The gate-drain capacitance is a feedback capacitance, and as the gate-drain capacitance increases, both the K-factor and the |S12| increase. The semiconductor device A can have a small gate-drain capacitance and can suppress the K-factor and the |S12|, with compared to the semiconductor device B.

The embodiments disclosed here should be considered illustrative in all respects and not restrictive. The present disclosure is not limited to the specific embodiments described above, but various variations and changes are possible within the scope of the gist of the present disclosure as described in the claims.

The embodiments disclosed here should be considered illustrative in all respects and not restrictive. The present disclosure is not limited to the specific embodiments described above, but various variations and changes are possible within the scope of the gist of the present disclosure as described in the claims.

What is claimed is:

1. A semiconductor device comprising:
a substrate;
a first transistor unit having a first drain electrode, a first gate electrode, and a first source electrode which are provided in order on the substrate;
a second transistor unit having a second source electrode arranged along the first source electrode and electrically connected to the first source electrode, a second gate electrode electrically connected to the first gate electrode, and a second drain electrode electrically connected to the first drain electrode, the second source electrode, the second gate electrode and the second drain electrode being provided in order on the substrate, the second transistor unit being located in a direction where the first drain electrode, the first gate electrode, and the first source electrode are arranged with respect to the first transistor unit;
a gate wiring provided on the substrate between the first source electrode and the second source electrode and adjacent to the first source electrode and the second source electrode, and electrically connected to the first gate electrode and the second gate electrode;
a first cover metal layer provided on and electrically connected to the first source electrode, at least an upper portion of the first cover metal layer projecting toward the gate wiring more than the first source electrode; and
a second cover metal layer provided on and electrically connected to the second source electrode, at least an upper portion of the second cover metal layer projecting toward the gate wiring more than the second source electrode.

2. The semiconductor device according to claim 1, wherein
at least a part of the first cover metal layer and at least a part of the second cover metal layer overlap with the gate wiring in a non-contact manner in plan view.

3. The semiconductor device according to claim 1, wherein
the first cover metal layer and the second cover metal layer are in contact with each other above the gate wiring.

4. The semiconductor device according to claim 3, wherein
a plurality of first portions where the first cover metal layer and the second cover metal layer are in contact with each other above the gate wiring and a plurality of second portions where the first cover metal layer and the second cover metal layer are not provided above the gate wiring are alternately provided along the gate wiring.

5. The semiconductor device according to claim 1, wherein
the first cover metal layer and the second cover metal layer are not in contact with each other above the gate wiring.

6. The semiconductor device according to claim 5, wherein
an end of the first cover metal layer overlaps with the gate wiring in plan view, and an end of the second cover metal layer overlaps with the gate wiring in the plan view.

7. The semiconductor device according to claim 1, further comprising:
a third transistor unit having a third drain electrode electrically connected to the first drain electrode, a third gate electrode electrically connected to the gate wiring, and a third source electrode electrically connected to the first source electrode, the third drain electrode, the third gate electrode and the third source electrode being provided in order on the substrate, the third transistor unit being located in a direction where the first gate electrode extends with respect to the first transistor unit.

8. The semiconductor device according to claim 7, further comprising:
a connection wiring that electrically connects the third gate electrode to the gate wiring between the first transistor unit and the third transistor unit;
wherein a part of the first cover metal layer overlaps with at least a part of the connection wiring in plan view.

9. The semiconductor device according to claim 1, further comprising:
a first drain wiring provided on the first drain electrode in electrical contact with the first drain electrode, a height from the substrate to an upper surface of the first drain wiring being smaller than a height from the substrate to an upper surface of the first cover metal layer; and
a second drain wiring provided on the second drain electrode in electrical contact with the second drain electrode, a height from the substrate to an upper surface of the second drain wiring being smaller than a height from the substrate to an upper surface of the second cover metal layer.

10. A semiconductor device comprising:
a substrate;
a first transistor unit having a first drain electrode, a first gate electrode, and a first source electrode which are provided in order on the substrate;
a second transistor unit having a second source electrode arranged along the first source electrode and electrically connected to the first source electrode, a second gate electrode electrically connected to the first gate electrode, and a second drain electrode electrically connected to the first drain electrode, the second source electrode, the second gate electrode and the second drain electrode being provided in order on the substrate, the second transistor unit being located in a direction where the first drain electrode, the first gate electrode, and the first source electrode are arranged with respect to the first transistor unit;
a gate wiring provided on the substrate between the first source electrode and the second source electrode and adjacent to the first source electrode and the second source electrode, and electrically connected to the first gate electrode and the second gate electrode;
a first source wiring provided on the first source electrode in electrical contact with the first source electrode;
a second source wiring provided on the second source electrode in electrical contact with the second source electrode;
a first drain wiring provided on the first drain electrode in electrical contact with the first drain electrode, a height of an upper surface of the first drain wiring from the substrate being smaller than a height of an upper surface of the first source wiring from the substrate; and
a second drain wiring provided on the second drain electrode in electrical contact with the second drain electrode, and a height of an upper surface of the second drain wiring from the substrate being smaller than a height of an upper surface of the second source wiring from the substrate.

11. The semiconductor device according to claim 10, further comprising:
a third transistor unit having a third drain electrode electrically connected to the first drain electrode, a third gate electrode electrically connected to the gate wiring, and a third source electrode electrically connected to the first source electrode, the third drain electrode, the third gate electrode and the third source electrode being provided in order on the substrate, the third transistor unit being located in a direction where the first gate electrode extends with respect to the first transistor unit.
